(19) United States
(12) Patent Application Publication
(10) Pub. No.: US 2026/0133497 A1
(43) Pub. Date: May 14, 2026

(54) MIRROR ASSEMBLY, ILLUMINATION OPTICAL UNIT HAVING A MIRROR ASSEMBLY, ILLUMINATION SYSTEM HAVING SUCH AN ILLUMINATION OPTICAL UNIT AND PROJECTION EXPOSURE APPARATUS HAVING SUCH AN ILLUMINATION SYSTEM

(71) Applicant: Carl Zeiss SMT GmbH, Oberkochen (DE)

(72) Inventors: Erik SOHMEN, Aalen (DE); Johannes BAUER, Giengen an der Brenz (DE)

(21) Appl. No.: 19/432,391

(22) Filed: Dec. 24, 2025

Related U.S. Application Data
(63) Continuation of application No. PCT/EP2024/067625, filed on Jun. 24, 2024.

(30) Foreign Application Priority Data
Jul. 3, 2023 (DE) 10 2023 206 272.0

(51) Int. Cl. G03F 7/00; G02B 26/10; G02B 26/12

(52) U.S. Cl. CPC G03F 7/702; G02B 26/105; G02B 26/122; G03F 7/7015; G03F 7/70025; G03F 7/70041

(57) ABSTRACT

A mirror assembly has a mirror with a mirror body and a reflection surface. A rotational drive device for at least one reflection surface support portion of the mirror body has a first motor and a second motor (30). The first motor has a stationary, first stator portion and a first rotor portion which is rotatable about a first axis of rotation. The second motor has a second stator portion, which is affixed to the first stator portion, and a second rotor portion, to which at least one rotor body portion of the mirror body is affixed and which is rotatable about a second axis of rotation. A normal to the reflection surface adopts an angle of greater than 0° with respect to the first and/or second axis of rotation. This results in a flexibly utilizable mirror assembly.

### CROSS-REFERENCE TO RELATED APPLICATIONS

The present application is a continuation of, and claims benefit under 35 USC 120 to, international application No. PCT/EP2024/067625, filed Jun. 24, 2024, which claims benefit under 35 USC 119 of German Application No. 10 2023 206 272.0, filed Jul. 3, 2023. The entire disclosure of each of these applications is incorporated by reference herein.

### FIELD

The disclosure relates to a mirror assembly having a mirror and a drive for a reflection surface support portion of a mirror body of the mirror. The disclosure also relates to an illumination optical unit having a mirror assembly with two scanning mirrors, an illumination system having such an illumination optical unit, a projection exposure apparatus having such an illumination system, a method for producing a microstructured or nanostructured component using such a projection exposure apparatus, and a microstructured or nanostructured component, such as a microchip, produced in this way.

### BACKGROUND

A mirror assembly is known from U.S. Pat. Nos. 6,704,095, 8,710,471 B2 and 9,678,432, for example.

### SUMMARY

The present disclosure seeks to develop a mirror assembly that it is utilizable as flexibly as is reasonably possible.

In an aspect, the disclosure provides a mirror assembly having a mirror with a mirror body and a reflection surface. The mirror assembly also has a rotational drive device for at least one reflection surface support portion of the mirror body. The rotational drive device comprises a first motor having a stationary first stator portion and a first rotor portion which is rotatable relative to the first stator portion about a first axis of rotation. The rotational device comprises a second motor having a second stator portion that is affixed to the first stator portion, coincides with the first rotor portion, or is affixed to the first rotor portion. The second motor also has a second rotor portion to which at least one rotor body portion of the mirror body is affixed and which is rotatable relative to the second stator portion about a second axis of rotation. A normal to the reflection surface adopts an angle of greater than 0° with respect to the first axis of rotation and/or with respect to the second axis of rotation.

According to the disclosure, it was recognized that a mirror assembly with two nested motors, each comprising a stator portion and a rotor potion, and with a reflection surface normal which is tilted in relation to at least one of the two motor axes of rotation leads to the possibility of using a reflection surface wobble movement obtainable thereby for targeted beam deflection. For example, the two motors can operate in synchronization and can operate at the same rotational frequency or else at purposefully different rotational frequencies. For example, the rotational frequencies of the two motors can be at an integer ratio to one another. An angle between the reflection surface normal on the one hand and at least one of the two axes of rotation on the other hand can be less than 20°, can be less than 10°, can be less than 5° and can be of the order of 3° or 2°, for example. In general, this angle is greater than 1°. This angle may also be exactly 0° in a further embodiment of the mirror assembly. The mirror assembly can comprise a shutter or interact with a shutter, the shutter being able to operate in synchronization with the rotational drive device for example. This can be used for the targeted deflection of an input beam into specific output directions via the mirror of the mirror assembly. For example, use of such a shutter makes it possible to avoid undefined operational states, such as with unwanted stray light. Further, the mirror assembly can also include an output coupling mirror which purposefully output couples light reflected by the (then first) mirror of the mirror assembly into a downstream beam path. A drive used to switch such an output coupling mirror between a first coupling position, in which illumination light guided via a beam path directed by the mirror assembly is output coupled into a defined downstream used beam path, and a further coupling position, in which there is no such guidance into the downstream used beam path, can be implemented in turn by way of a drive motor. Such a drive motor can be synchronized with other motors in the mirror assembly.

The two axes of rotation can adopt an angle of greater than 0° with respect to one another. Such an angle between the two axes of rotation of the two rotational drive device motors was found to be desirable in relation to a combination of, firstly, justifiable structural complexity of the rotation device and, secondly, a desirable deflection effect on account of the driven reflection surface support portion. The angle between the two axes of rotation can be less than 20°, can be less than 10°, can be less than 5° and can be of the order of 3° or 2°. This angle is regularly greater than 1°. In a special embodiment, the angle between the two axes of rotation can also be exactly 0°.

The two axes of rotation can intersect within the first stator portion. Such an arrangement of the two axes of rotation was found to be suitable for the beam deflection via the reflection surface supported by the reflection surface support portion. The point of intersection between the two axes of rotation can be firstly located as close as possible to the reflection surface and can be secondly, in turn, close to drive components for the second rotor portion. Distances between the crossing point and the reflection surface and/or between the crossing point and drive components of the second rotor portion can be less than 10 cm, can be less than 5 cm and can also be less than 2 cm. These distances are regularly greater than 5 mm.

The two motors can be equipped with a motor controller for independently specifying the following: a rotational speed of the first motor; and/or a rotational speed of the second motor; and/or a phase of a position of the first rotor portion; and/or a phase of a position of the second rotor portion. Such a motor controller can help enable precise synchronization between the two motors of the rotational drive device in the mirror assembly. This may be useful for defined beam guidance.

The mirror body can have a two-piece design and comprise: the reflection surface support portion; and the rotor body portion, wherein the reflection surface support portion is rotatably mounted on the rotor body portion. Such a two-piece mirror body can help prevent the reflection surface support portion from rotating. This then renders possible an embodiment of the mirror assembly in which the reflection surface support portion performs only a tilt-wobble movement without a complete rotational movement through 360° when both motors of the rotational drive device are driven. This then allows ports for external supply devices to be attached to the reflection surface support portion, for example a rinsing supply, a power supply or else a fluid heat transfer medium supply for cooling the reflection surface. The aforementioned features can come to bear in the case of a reflection surface support portion of the mirror body comprising a line portion of a fluid heat transfer medium line. The fluid heat transfer medium line can be flexibly designed adjacent to the line portion of the reflection surface support portion in order to compensate for tilt-wobble movements of the reflection surface support portion. The fluid heat transfer medium line can be part of a cooling device for cooling the reflection surface of the mirror assembly. The cooling device can be used to guide fluid heat transfer medium in a circuit via the fluid heat transfer medium line. Water can be used as fluid heat transfer medium.

The present disclosure also seeks to provide an illumination optical unit that can enable a flexible illumination of an object field.

In an aspect, the disclosure provides an illumination optical unit having: a mirror assembly with a first scanning mirror; a further scanning mirror arranged in the region of a pupil plane of the illumination optical unit; and a scan controller for scanning an object field of the illumination optical unit, which is signal-connected to the motor controller, wherein a reticle is arrangeable in the object field.

According to the disclosure, it was recognized that an illumination optical unit having at least two scanning mirrors, with one of these scanning mirrors being arranged in the region of a pupil plane of the illumination optical unit, offers the possibility of a flexible illumination, for example the possibility of a flexible specification of an illumination angle distribution of the object field. In this case, the first scanning mirror can be used to specify an illumination intensity distribution within the pupil plane of the illumination optical unit. The further scanning mirror can then help ensure a specified illumination intensity distribution over the object field. The scan controller of the illumination optical unit can be signal-connected to scan drives of the scanning mirrors, for example for synchronization purposes. The illumination optical unit can represent an optical assembly in a lithographic projection exposure apparatus.

The further scanning mirror can be designed as a rotating polygon mirror. Such a polygon mirror was found to be suitable for use as a further scanning mirror. The polygon mirror can comprise at least three polygon facets, for example five, six, eight, ten or even more than ten polygon facets. The number of polygon facets of the polygon mirror is regularly less than 50.

The object field can be designed to be ring portion-shaped, arcuate or else rectangular.

The mirror assembly of an illumination optical unit can be embodied according to the description above in the summary. The mirror of the mirror assembly can represent the first scanning mirror in the illumination optical unit.

The mirror of the mirror assembly of an illumination optical unit can then be used to specify an illumination setting of the illumination optical unit. In this case, a synchronization of the rotational drive device motors is desirable for example, for example a synchronization of the motor controller and the scan controller, which in turn can interact with a drive for the further scanning mirror.

The further scanning mirror of an illumination optical unit can be embodied as a grazing incidence (GI) mirror or an a normal incidence (NI) mirror. An embodiment as a GI mirror can help enable a relatively high reflection efficiency of the further scanning mirror, which can be desirable if the used light guided by the illumination optical unit is EUV light in the wavelength range between 5 nm and 30 nm. An NI mirror can help allow for a compact embodiment of the further scanning mirror.

An illumination system can include an illumination optical unit described above in the summary and a light source. The light source can be a plasma light source.

A light source can be a free electron laser (FEL). The can be desirable on account of the stability of the FEL and its high beam quality.

A light source controller can be synchronized with the at least one motor controller of the mirror assembly and/or with the scan controller of the illumination optical unit in the case of a light source that operates in pulsed fashion. Then, stable illumination settings can be created using the illumination optical unit. Different illumination settings, for example an x-dipole setting, a y-dipole setting, a quadrupole setting or a hexapole setting, can be created depending on the way the motors of the mirror assembly are controlled. Other illumination settings, for example a conventional illumination setting with, integrated over time, an illumination pupil that is filled as completely as reasonably possible or an annular illumination setting, can also be generated by appropriate control of the motors of the rotational drive device.

In an aspect, the disclosure provides projection exposure apparatus for projection lithography. The apparatus has an illumination system as described above in the summary. The apparatus can also have a projection optical unit for imaging the object field in an image field in which a substrate is arrangeable.

In an aspect, the disclosure provides a method for producing a structured component, including the following steps: providing a reticle and a wafer; projecting a structure on the reticle onto a light-sensitive layer of the wafer using a projection exposure apparatus described above in the summary; and creating a microstructure and/or nanostructure on the wafer.

In an aspect, the disclosure provides a structured component or element formed by such a method.

The features of such a projection exposure apparatus, such a production method, and such a structured component or element can correspond to those which have already been explained above in the summary with reference to the illumination system. A structured element, such as a microchip, for example a memory chip, can be produced.

### BRIEF DESCRIPTION OF THE DRAWINGS

At least one exemplary embodiment of the disclosure is described hereinafter with reference to the drawings, in which:

FIG. 1 schematically shows a meridional section of a projection exposure apparatus for EUV projection lithography;

FIG. 2 shows, in certain detail, a beam path of a projection exposure apparatus variant having an illumination optical unit for illuminating an object field of the projection exposure apparatus, wherein the illumination optical unit comprises a mirror assembly with two nested motors with axes of rotation, angled with respect to one another, for the rotating tilt drive of a reflection surface support portion of a mirror body with a reflection surface, wherein a bent or ring portion-shaped object field is illuminated;

FIG. 3 shows, in enlarged fashion, a mirror assembly variant for use in the illumination optical unit according to FIG. 2, wherein a mirror body is fully affixed to a rotor portion of a second motor of a rotational drive device in this variant of the mirror assembly;

FIGS. 4 to 12 show the mirror assembly according to FIG. 3 in different phase positions of the two motors of the rotational drive device, wherein an associated illumination intensity distribution over an illumination optical unit pupil plane disposed downstream of the mirror assembly in an illumination light beam path is depicted therebelow in each case;

FIGS. 13 to 16 show further illumination intensity distributions in the illumination optical unit pupil plane, created by different phase relationships and rotational frequencies of the two motors of the rotational drive device of the mirror assembly, synchronized with a pulsed light source for the illumination light;

FIG. 17 shows a further scanning mirror of the illumination optical unit in the form of a rotating polygon mirror which is disposed in the region of the illumination optical unit pupil plane, downstream of the mirror assembly in the illumination light beam path;

FIG. 18 shows an example of an object field lighting, created by the illumination optical unit according to FIG. 2 with an appropriate ratio between a rotational frequency of the further scanning mirror and a pulse frequency of the light source, operating in pulsed fashion, of a projection exposure apparatus illumination system which comprises the illumination optical unit;

FIG. 19 shows, in an illustration similar to FIG. 3, a further embodiment of the mirror assembly with a mirror body attached at a different angle in comparison with the rotor portion of the second motor;

FIG. 20 shows, once again in an illustration similar to FIG. 3, a further embodiment of the mirror assembly having a mirror body, which is divided into a reflection surface support portion and a rotor portion, wherein fluid cooling of the reflection surface support portion is indicated by way of a line portion of a fluid heat transfer medium line;

FIG. 21 shows, in an illustration similar to FIG. 2, an illumination system having the illumination optical unit corresponding to that according to FIG. 1 and a light source for the illumination light embodied as an FEL (free electron laser); and

FIG. 22 shows, once again in an illustration similar to FIG. 2, a variant of the illumination system for illuminating a rectangular object field.

### DETAILED DESCRIPTION

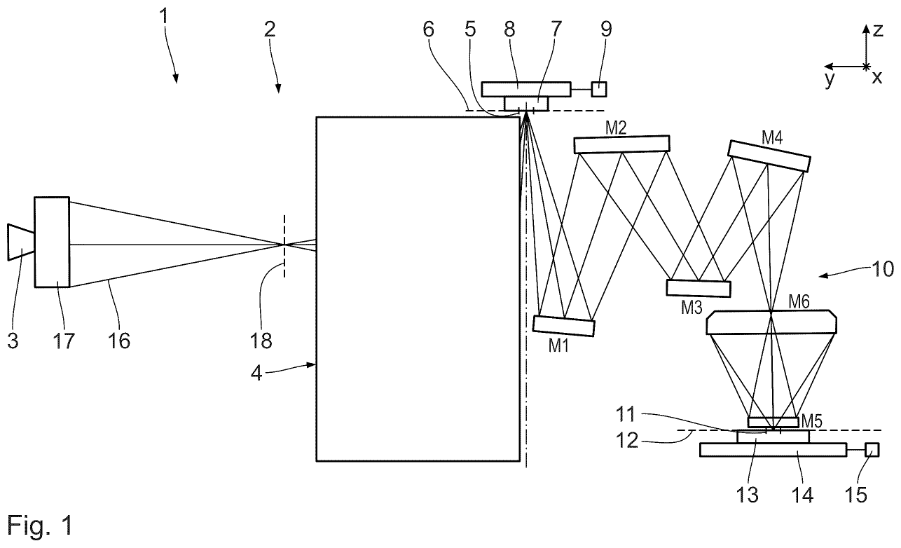

Certain components of a microlithographic projection exposure apparatus 1 are first described by way of example hereinafter with reference to FIG. 1. The description of the basic setup of the projection exposure apparatus 1 and its components should not be regarded as limiting here.

One embodiment of an illumination system 2 of the projection exposure apparatus 1 has, in addition to a light or radiation source 3, an illumination optical unit 4, indicated schematically in FIG. 1, for illuminating an object field 5 in an object plane 6. The object field 5 can be embodied as a rectangular field or else as an arcuate field or ring portion-shaped field. In an alternative embodiment, the light source 3 may also be provided in the form of a module separate from the rest of the illumination system. In this case, the illumination system does not comprise the light source 3.

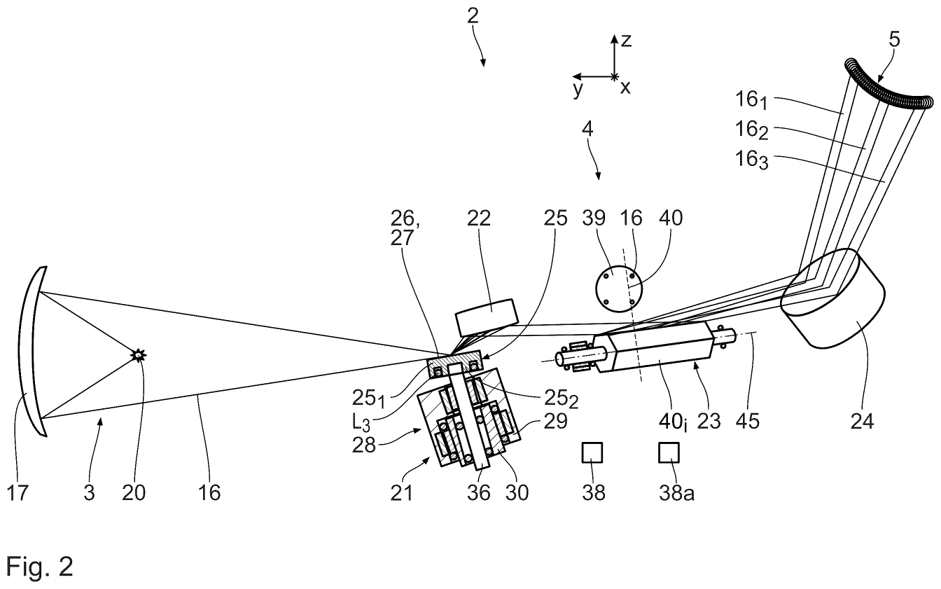

Variants of the illumination optical unit 4 and illumination system 2 will still be explained below with reference to FIG. 2 ff.

A reticle 7 arranged in the object field 5 is exposed. The reticle 7 is held by a reticle holder 8. The reticle holder 8 is displaceable, for example in a scanning direction, by way of a reticle displacement drive 9.

FIG. 1 shows a Cartesian xyz-coordinate system for explanatory purposes. The x-direction runs perpendicular to the plane of the drawing. The y-direction runs horizontally, and the z-direction runs vertically. The scanning direction runs in the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle between the object plane 6 and the image plane 12 can also be different from 0°.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits, for example, EUV radiation 16, which is also referred to below as used radiation, illumination radiation or illumination light. For example, the used radiation has a wavelength in the range of between 5 nm and 30 nm. The radiation source 3 can be a plasma source, for example an LPP (laser produced plasma) source or a GDPP (gas discharge produced plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optical unit 4.

The illumination radiation 16 initially travels horizontally, i.e. in the y-direction, downstream of the collector 17.

The illumination optical unit 4 is used to create a defined illumination angle distribution over the object field 5; this illumination angle distribution is also referred to as illumination setting. This is still explained below with reference to FIG. 2 ff.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi can be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may comprise highly reflective coatings for the illumination radiation 16. These coatings may be in the form of multi-layer coatings, for example with alternating layers of molybdenum and silicon.

The projection optical unit 10 has a large object-image offset in the y-direction between a y-coordinate of a centre of the object field 5 and a y-coordinate of the centre of the image field 11. In the y-direction, this object-image offset can be of approximately the same magnitude as a z-distance between the object plane 6 and the image plane 12.

The projection optical unit 10 may for example have an anamorphic form. For example, it has different imaging scales βₓ, β_{y} in x- and y-directions. The two imaging scales βₓ, β_{y} of the projection optical unit 10 can be at (βₓ, β_{y})=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 may be the same or may be different depending on the embodiment of the projection optical unit 10. Examples of projection optical units with different numbers of such intermediate images in the x- and y-directions are known from US 2018/0074303 A1.

Further aspects and details of the lighting of the object field 5 and for example of the entrance pupil of the projection optical unit 10 are described hereinafter.

The projection optical unit 10 may have a homocentric entrance pupil for example. The latter can be accessible. It can also be inaccessible.

The entrance pupil of the projection optical unit 10 regularly cannot be illuminated exactly via the illumination optical unit 4. The aperture rays often do not intersect at a single point in the event of imaging by the projection optical unit 10, which images the centre of a pupil defined by the illumination optical unit 4 telecentrically onto the wafer 13. However, it is possible to find a surface area in which the spacing of the aperture rays, which is determined in pairs, becomes minimal. This surface area represents the entrance pupil or a surface area in real space that is conjugate thereto. For example, this surface area exhibits a finite curvature.

It may be the case that the projection optical unit 10 has different positions of the entrance pupil for the tangential beam path and for the sagittal beam path. In this case, an imaging element of the illumination optical unit 4 should be provided upstream of the reticle 7. The different positions of the tangential entrance pupil and the sagittal entrance pupil can be taken into account using this optical element.

FIG. 2 shows a variant of the illumination system 2 with the illumination optical unit 4 which can be used in the projection exposure apparatus 1. Components and functions corresponding to those which have already been explained above with reference to FIG. 1 bear the same reference signs and will not be discussed in detail again.

A variant of the collector 17 in the form of an ellipsoid NI mirror is used in the illumination system 2 according to FIG. 2. A source volume 20 of the light source 3, which is embodied as a plasma source in this case, of the projection exposure apparatus 1 is arranged at a focus of the collector 17.

The light source 3 is operated in pulsed fashion with a pulse frequency F_{L}. Thus, the illumination light 16 is available in the form of a pulse train, wherein a time interval between two temporally adjacent individual pulses in this pulse train corresponds to the pulse frequency F_{L}.

Components of the illumination optical unit 4 disposed downstream of the collector 17 in the beam path of the illumination light 16 are a mirror assembly 21, which is still explained in detail hereinbelow; a downstream deflection mirror 22; a rotating polygon mirror 23 which is disposed further downstream; and a further deflection mirror 24 which is disposed even further downstream and guides the illumination light 16 to the object field 5.

The object field 5 is embodied as a ring field in the embodiment according to FIG. 2.

For illustrative purposes, the object field 5 has been depicted in a slightly perspective plan view in FIG. 2. In fact, the object field 5 extends parallel to the xy-plane like in the embodiment according to FIG. 1, with a longer extent of the ring portion-shaped object field 5 extending along the x-axis and a short transverse extent of the object field 5 extending along the y-axis (scanning direction=y-direction).

For illustrative purposes, FIG. 2 indicates beam paths of three illumination light component beams 16₁, 16₂ and 16₃, which correspond to different momentary reflection positions of the polygon mirror 23 for example.

The mirror assembly 21 according to FIG. 2 has a two-piece mirror body 25 having a reflection surface support portion 25₁ and having a rotor body portion 25₂.

The reflection surface support portion 25₁ supports a reflection surface 26 of the mirror body 25. A further focus of the ellipsoid collector 17 is located in the region of a reflection of the illumination light 16 at the reflection surface 26.

Together with the mirror body 25, the reflection surface 26 forms a mirror 27 of the mirror assembly 21.

A rotational drive device 28 serves to drive a scanning movement of the reflection surface support portion 25₁ of the mirror body 25 via the rotor body portion 25₂ and hence serves to drive a scanning movement of the reflection surface 26.

The rotational drive device 28 comprises a first motor 29 and a second motor 30.

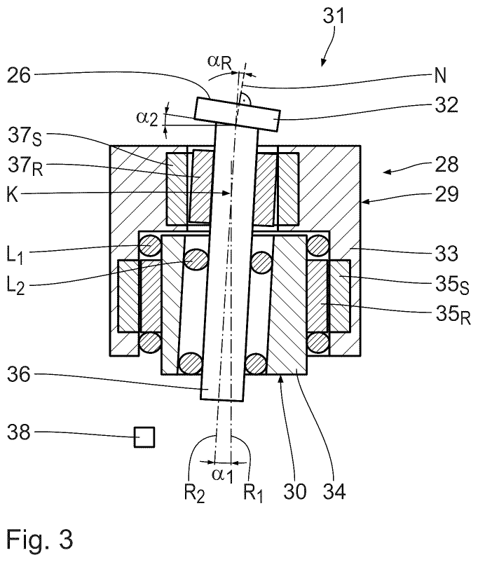

FIG. 3, which shows a further embodiment of a mirror assembly 31 with a one-piece mirror body 32, illustrates details of the rotational drive device 28 which is also used in this form in the mirror assembly 21 according to FIG. 2.

The first motor 29 has a stationary outer stator portion 33 and a first rotor portion 34 which is rotatable relative to the first stator portion 33 about a first axis of rotation R₁ of the first motor 29. The first motor 29 is embodied as an electric motor. Stator windings 35_{S} and rotor windings 35_{R} of the first motor 29 are emphasized in FIG. 3 by respective hatching or fill patterns.

The second motor 30, likewise embodied as an electric motor, of the rotational drive device 28 in turn has a second stator portion which is affixed to the first stator portion 33 in the case of the embodiment according to FIG. 3 but which may also coincide with the first rotor portion 34 of the first motor 29. Alternatively, the second stator portion of the second motor 30 can be affixed to the first rotor portion 34 of the first motor 29.

The two stator portions of the first motor 29 and second motor 30 can be integrated together, as one piece, in an outer housing of the rotational drive device 28.

The second motor 30 also has a second rotor portion 36 embodied as a rotor shaft, affixed to which is the entire mirror body 32 in the case of the embodiment according to FIG. 3 or the rotor body portion 25₂ of the mirror body 25 in the case of the embodiment of the mirror assembly 21 according to FIG. 2.

Stator and rotor windings of the second motor 30 are illustrated at 37_{S} and 37_{R} in FIG. 2.

The stator windings 37_{S} of the second motor 30 are arranged in the region of the first stator portion 33 of the first motor 29. Alternatively, these stator windings 37_{S} may also be arranged in the region of the second stator portion 34 of the second motor 30.

The rotor windings 37_{R} of the second motor 30 are affixed to the rotor shaft 36.

The second motor 30 has a second axis of rotation R₂. The second axis of rotation R₂ runs along a shaft axis of the second rotor portion 36 of the second motor 30.

The two axes of rotation R₁, R₂ of the two motors 29, 30 of the rotational drive device 28 are at an angle α₁ with respect to one another, the angle being approximately 3° in the embodiment according to FIGS. 2 and 3. Depending on the embodiment of the mirror assembly 21 or 31, this angle α₁ is regularly less than 20°, less than 10° and also less than 5°. In general, this angle α₁ is greater than 1°. In principle, the angle α₁ may also be 0°.

The two axes of rotation R₁, R₂ intersect at a crossing point K, which is located within the first stator portion 33.

In the mirror assemblies 21 and 31, a normal to the reflection surface 26 makes an angle α₂ of greater than 0° with the second axis of rotation R₂, and this angle once again is of the order of 3° in the embodiment according to FIGS. 2 and 3. In respect of possible angular ranges, the explanations given above with respect to the angle α₁ apply.

The first rotor portion 34 is axially and radially mounted in the first stator portion 33 by way of a roller bearing L₁.

The rotor shaft 36, i.e. the second rotor portion, is axially and radially mounted in the second stator portion 34 of the second motor 30 by way of a further roller bearing L₂.

In the mirror assembly 21 according to FIG. 2, the reflection surface support portion 25₁ is mounted by way of a further roller bearing L₃ on the rotor body portion 25₂, which in turn is affixed to an end portion of the rotor shaft 36. This mount is also both axial and radial.

A motor controller 38, which is schematically reproduced in FIG. 3, serves to independently specify rotational speeds and phases of the two motors 29, 30, i.e. a rotational speed or rotational frequency F₁ of the first motor 29, a rotational speed or rotational frequency F₂ of the second motor 30, a phase P₁ of a rotational position of the first rotor portion of the first motor 29 and a phase P₂ of a rotational position of the second rotor portion 36 of the second motor 30, i.e. the rotor shaft.

Additionally, the illumination optical unit 4 has a scan controller 38a, which is signal-connected to the motor controller 38 and optionally to a motor controller of at least one further scanning mirror of the illumination optical unit and also to a controller of the light source 3.

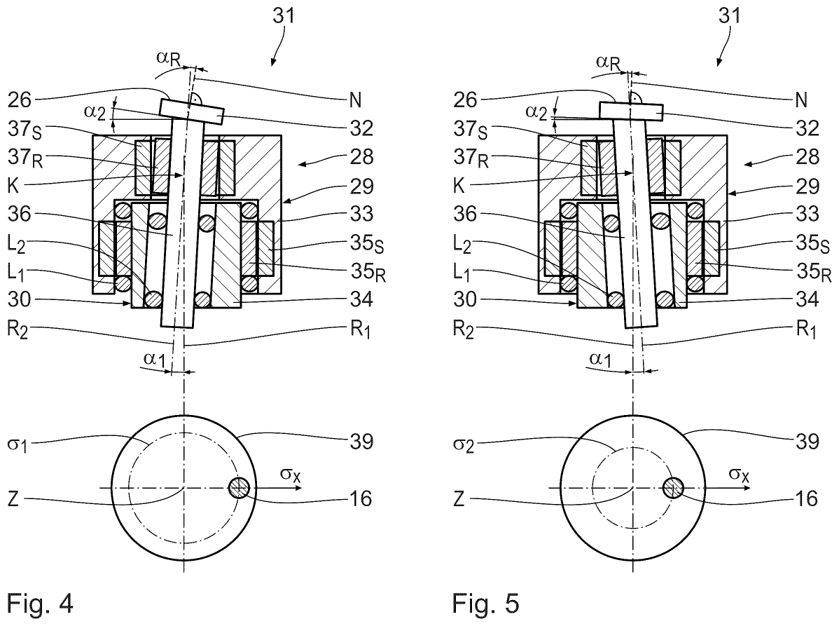

FIGS. 4 to 12 show various combinations of rotational position phases P₁ and P₂ of the two motors 29 and 30. Moreover, the lower parts of FIGS. 4 to 12 show respective momentary positions of a beam of the illumination light 16 in a pupil 39 located in a pupil plane 40, in the region of which the illumination light 16 is reflected at a respective facet 40ᵢ of the polygon mirror 23. The pupil 39 is also illustrated in FIG. 2 in a plan view.

FIG. 4 shows a 0°/0° phase relationship of the two motors 29, 30. This results in an angle α_{R} between the axis of rotation R₁ and the normal N to the reflection surface 26, to which the following applies: α_{R}=α₁+α₂. In the pupil 39, this results in an illumination spot position for the illumination light 16 which corresponds to a relatively large illumination angle σ₁ in the object field 5 on account of the addition of the deflection angles α₁ and α₂.

FIG. 5 shows the relationships in the case of a 180°/0° phase combination of the two motors 29, 30. In this case, the two angles α₁ and α₂ subtract to form a smaller resultant angle α_{R}, and this leads to an illumination spot position of the illumination light 16 at an illumination angle σ₂. The following applies: σ₂<σ₁.

The respective illumination angle σᵢ arises as the distance between an illumination spot centre of the illumination light 16 and a centre Z of the illumination pupil 39.

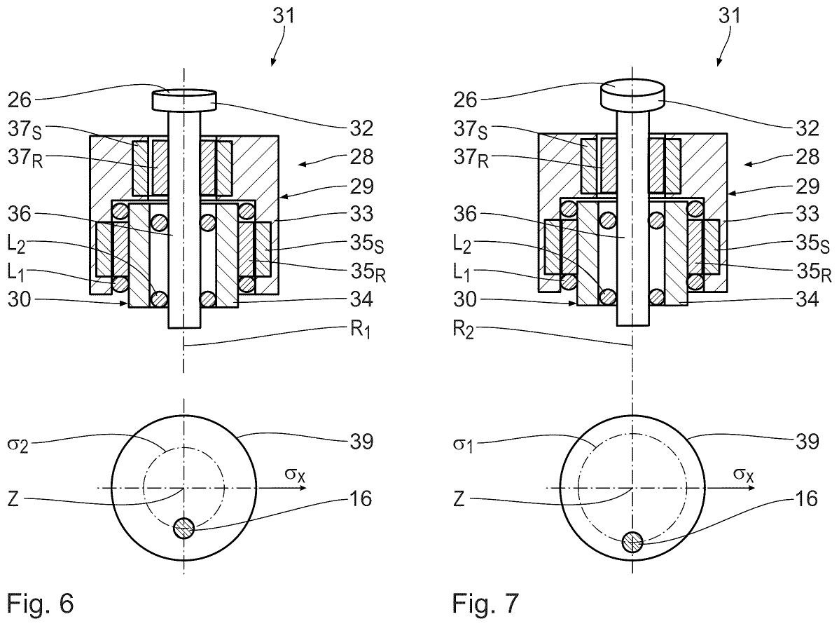

FIG. 6 shows the 90°/90° phase combination, which once again leads to a subtraction of the angles α₁ and α₂. Unlike the phase combination according to FIG. 5, the spot of the illumination light 16 is arranged in the pupil 39 not at “3 o'clock” but at “6 o'clock” in the phase combination according to FIG. 6.

FIG. 7 shows the relationships corresponding to FIG. 6, albeit in the case where the angles α₁ and α₂ are added (phase combination 270°/90°). The spot of the illumination light 16 is now at the “6 o'clock” position and at an illumination angle σ₁.

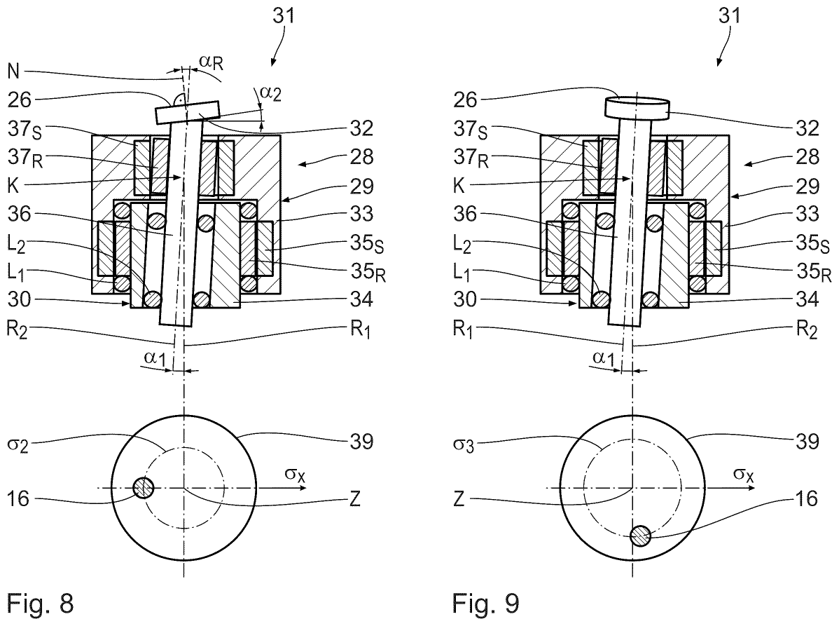

FIG. 8 shows the 0°/180° phase combination. This combination corresponds to that of FIG. 5, with the difference that the spot of the illumination light 16 is now located at the “9 o'clock” position.

FIG. 9 shows the 0°/90° phase combination. The resultant spot position substantially corresponds to that according to FIG. 7.

An illumination angle σ₃ to which the following applies is obtained in the situation according to FIG. 9: σ₁>σ₃>σ₂.

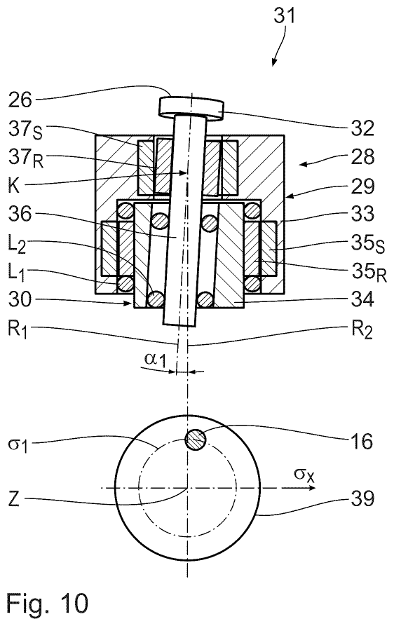

FIG. 10 shows the phase combination 0°/270° which in respect of the illumination spot position of the illumination light 16 leads to a mirroring of the situation according to FIG. 9 about a horizontal axis σₓ of the illumination pupil 39.

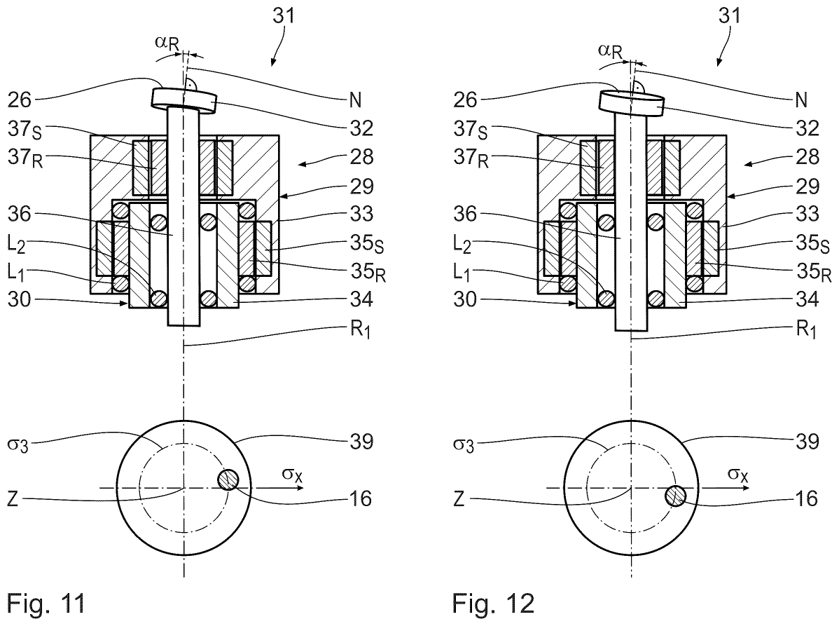

FIG. 11 shows the 90°/0° phase combination which is comparable to that according to FIG. 4, albeit at an illumination intermediate angle σ₃.

FIG. 12 shows the 270°/0° phase combination which in principle again corresponds to that according to FIG. 4, again with the illumination intermediate angle σ₃ in this case.

In a manner comparable to the pupil illustrations in FIGS. 4 to 12, FIGS. 13 to 16 show, by way of example, illumination spot lighting situations of the pupil 39 for different phase combinations P₁ and P₂ of the motors 29 and 30 and, additionally, for different combinations of the rotational frequencies F₁, F₂ of the motors 29 and 30.

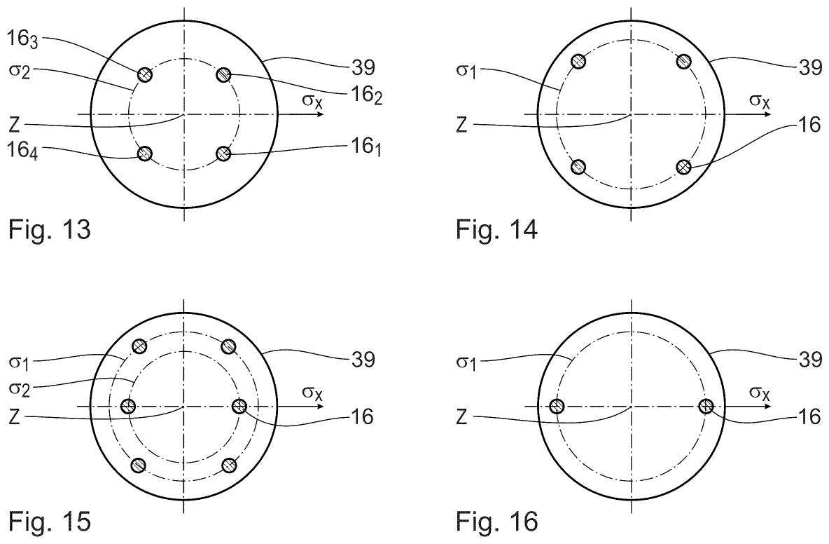

FIG. 13 shows a situation in which the two motors, proceeding from a 135°/45° phase combination, are each operated at a rotational frequency F₁/F₂ which is a quarter of a pulse frequency F_{L} of the light source 3 operated in pulsed fashion.

A quadrupole illumination setting with the smallest illumination angle σ₂ arises for the pupil 39 with these rotational speed/phase relationships according to FIG. 13. Four successive individual pulses 16₁ to 16₄ of the light source 3 then create the four poles of this quadrupole illumination setting.

FIG. 14 shows the relationships with the same rotational speed relationships in comparison with FIG. 13 and with a 45°/45° phase combination, for which the angles α₁ and α₂ are once again added. The result is a quadrupole illumination setting with a large illumination angle σ₁.

By way of example, the quadrupole setting according to FIG. 14 is also depicted adjacent to the polygon mirror 23 in FIG. 2.

FIG. 15 shows the illumination situation for the frequency relationships F₁=½ F_{L} and F₂=⅙ F_{L}, and a −90°/90° phase combination. This results in a hexapole illumination setting, wherein four of the six individual poles of the illumination setting according to FIG. 15 have a larger illumination angle of the order of the angle σ₃, and two illumination poles have a slightly smaller illumination angle in comparison therewith, of the order of the angle σ₂.

FIG. 16 shows an illumination situation with frequency relationships of F₁=F₂=½ F_{L} and 90°/90° phase relationships of the two motors 29 and 30. This results in an x-dipole illumination setting with a large illumination angle σ₁.

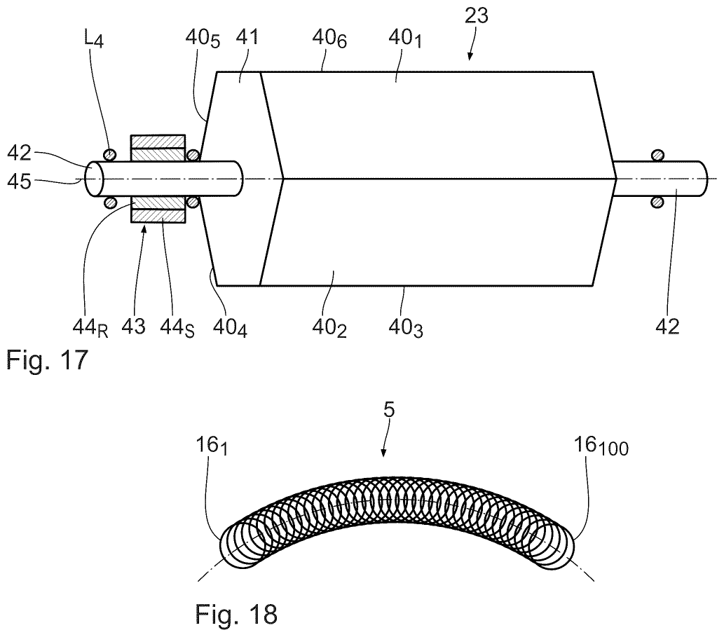

FIG. 17 provides a detailed view of the polygon mirror 23, which is arranged in the pupil plane 40 and which ensures that the illumination setting created by way of the mirror assembly 21 or 31 is fanned open, i.e. it ensures scanning of the illumination light 16 over the entire object field 5, as elucidated on the basis of FIG. 2 and FIG. 18 which follows.

The polygon mirror 23 has a cylindrical mirror body 41 with a hexagonal cross section. This results in six facets 40₁ to 40₆ as lateral surface portions of this cylindrical mirror body 41. The latter is connected to a shaft 42 which is axially and radially mounted on a mirror support by way of a further bearing L₄ and which is rotationally driven by way of a further motor 43, which in turn is designed as an electric motor and comprises stator windings 44_{S} and rotor windings 44_{R}.

A rotational frequency F₃ of the mirror body 41 about an axis of rotation 45 of the polygon mirror 23 is in the range of between 1:500 and 1:20 of the pulse frequency F_{L} of the light source 3, for example in the range of between 1:100 and 1:20. In accordance with this ratio, the object field 5 for example subdivided into 100 individual illumination spots 16ᵢ is raster scanned in overlaid fashion, as illustrated in FIG. 18. Adjacent illumination spots 16ᵢ, 16ᵢ₊₁ thereof cover one another to at least 75%, with the result that a full raster scan or a full scan of the object field 5 by way of the illumination spots 16ᵢ is ensured.

In the polygon mirror 23, the polygon facets 40ᵢ are operated with grazing incidence of the illumination light 16. Thus, these polygon facets 40ᵢ each are GI mirrors with a high effective reflectivity.

The axis of rotation 45 of the polygon mirror 23 runs in a meridional plane (yz-plane) of the illumination optical unit 4 for example (cf. FIG. 2).

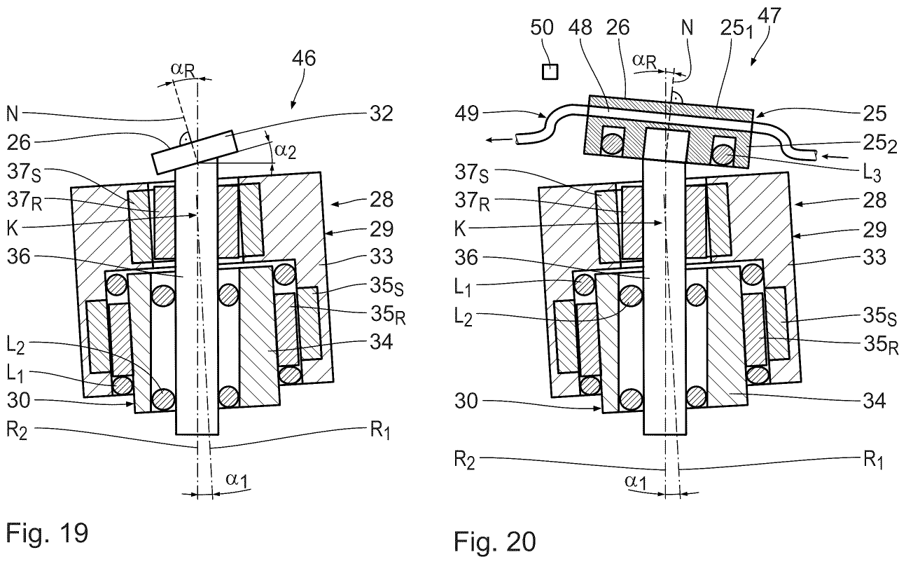

FIG. 19 shows a further embodiment of a mirror assembly 46 that can be used instead of the mirror assembly 21 or 31. Components and functions that correspond to those which were already explained above with reference to FIGS. 1 to 18, and for example with reference to FIGS. 2 and 3, bear the same reference signs and are not discussed in detail again.

The angle α₂ between the normal N and the second axis of rotation R₂ is greater than the angle α₁ between the two axes of rotation R₁ and R₂ in the mirror assembly 46. This angle α₂ is approximately 12° in the case of the mirror assembly 46. The angle α₁ is once again approximately 3° in this mirror assembly 46. For example, this significantly larger angular difference between the angles α₁ and α₂ results in a relatively large travel between a minimum illumination angle σ₁ and a maximum illumination angle σ₂ when an illumination setting corresponding to that explained above for example in the context of FIGS. 4 to 16 is specified. It is possible to provide a larger maximum illumination angle σ₁ and/or a smaller minimum illumination angle σ₂.

Otherwise, the structure of the mirror assembly 46 corresponds to that of the mirror assembly 31 according to FIG. 3.

FIG. 20 shows a further embodiment of a mirror assembly 47, which can be used in place of one of the mirror assembly variants explained above. Components and functions that correspond to those which have already been explained above with reference to FIGS. 1 to 19, and for example with reference to FIG. 2, bear the same reference signs and will not be discussed in detail again.

The mirror body 25 of the mirror assembly 47 is actively cooled by way of a fluid heat transfer medium. To this end, the reflection surface support portion 25₁ has a line portion 48 of a fluid heat transfer medium line 49. The line portion 48 can be embodied as a drilled hole extending in parallel with the reflection surface 26. In an alternative to that or in addition, the line portion 48 can for example be embodied as a meandering or snaking line in the reflection surface support portion 25₁ of the mirror body 25. Apart from the line portion 48, the structure of the mirror body 25 in the mirror assembly 47 corresponds to the structure of the mirror body in the mirror assembly 21 according to FIG. 2.

In the flow path of the fluid heat transfer medium upstream and downstream of the line portion 48, the fluid heat transfer medium line 49 has a flexible embodiment and for example is made of a plastic material, for example Teflon (PTFE) or silicone.

Since the reflection surface support portion 25₁ does not rotate about the axes of rotation R₁ and R₂ as a result of the rotationally mounted split of the mirror body 25 into two, this reflection surface support portion 25₁ performs not a rotational movement but a tilt/wobble movement as specified by the angles α₁ and α₂. A trajectory of this wobble movement is determined by the phase combination and the rotational speed ratios as explained above, especially in the context of FIGS. 13 to 16.

The flexible portions of the fluid heat transfer medium line 49, which adjoin the line portion 48 in the reflection surface support portion 25₁ of the mirror body 25, compensate this wobble movement within the fluid heat transfer medium line 49, with the result that the remaining components of an active cooling device 50, which for example ensures a circulation and cooling of the fluid heat transfer medium guided in the fluid heat transfer medium line 49, can be assembled stationarily in relation to a frame, especially of the illumination optical unit 4 of the projection exposure apparatus 1. The cooling device 50 is reproduced schematically in FIG. 20 and comprises a circulation pump for the fluid heat transfer medium and a cooling apparatus. Directional arrows illustrating a flow of the fluid heat transfer medium through the fluid heat transfer medium line 49 are respectively indicated at the start and end of the overall portion of the fluid heat transfer medium line 49 depicted in FIG. 20.

Water can be used as fluid heat transfer medium.

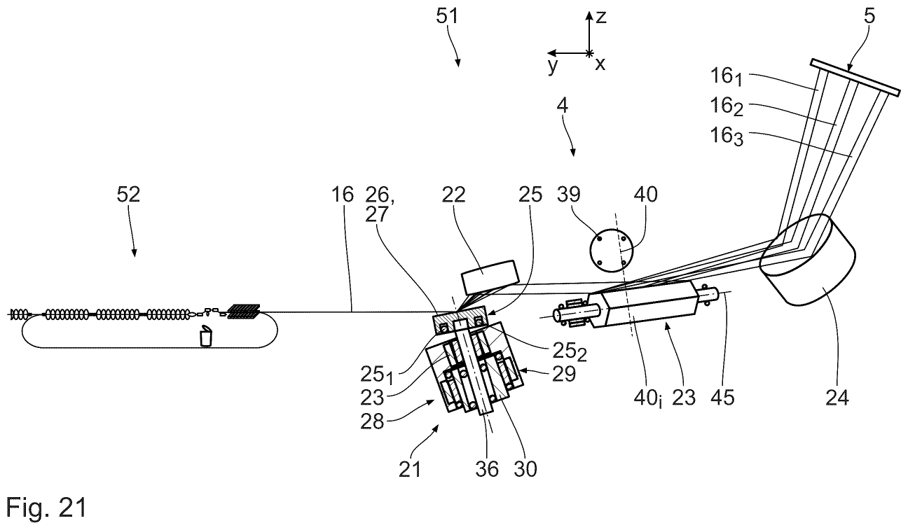

In an illustration corresponding to FIG. 2, FIG. 21 shows a further embodiment of an illumination system 51, which can be used in place of the illumination system 2. Components and functions corresponding to those which have already been explained above with reference to FIGS. 1 to 20, and for example with reference to FIGS. 2, 3 and 17, bear the same reference signs and will not be discussed in detail again.

A light source 52 of the illumination system 51 which can be used in place of a plasma light source according to FIG. 1 is embodied as an FEL (free electron laser). FIG. 21 schematically indicates assemblies of such an FEL light source 52, specifically an electron source, a three-stage linear accelerator, an electron beam manipulation unit for deflecting the electron beam and for creating appropriate synchrotron radiation, and a downstream undulator. Moreover, FIG. 21 indicates a circulatory guidance of the electrons.

A beam guidance of the illumination light 16 created by the FEL light source 52 fundamentally corresponds to that explained on the basis of FIG. 2 for example. Only a beam diameter of an overall illumination light beam guided from the FEL light source 52 to the mirror assembly 21 has a much smaller diameter than in the case of the used light output of the plasma light source 3 on account of the much smaller étendue of the FEL light source 52. Accordingly, the illumination spots 16ᵢ of the illumination light 16 in the pupil 39, which are created by the mirror assembly 21, or the further embodiments of the mirror assembly as explained above, in accordance with the specified illumination setting, are much smaller when the FEL light source 52 is used rather than the plasma light source 3.

When the FEL light source 52 is used, the illumination optical unit 4 can be equipped with étendue-increasing or beam-widening mechanisms or components, as known from U.S. Pat. No. 9,678,432, for example.

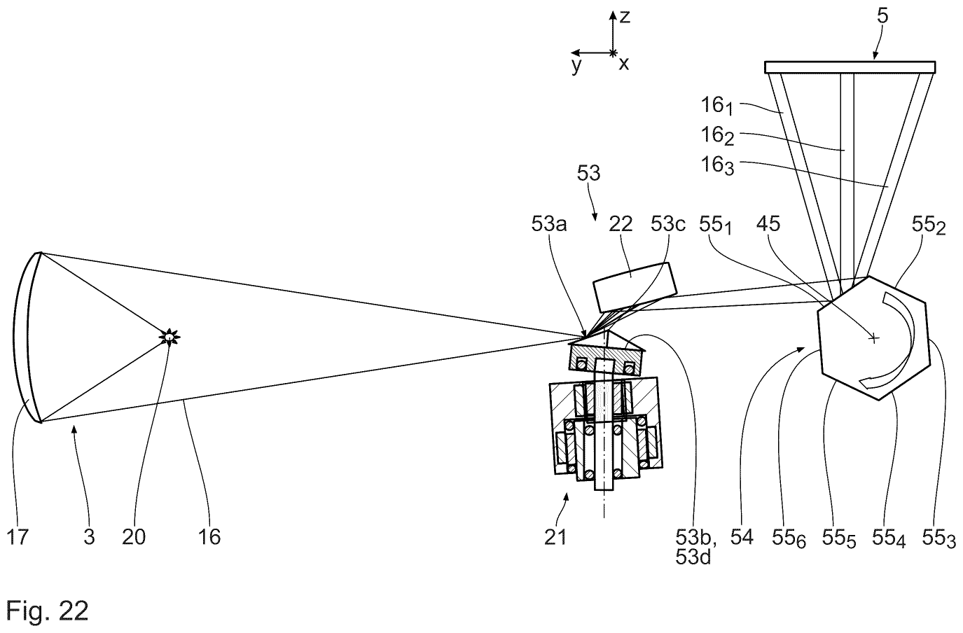

FIG. 22 shows a further embodiment of an illumination optical unit 53, which can be used in place of the illumination optical unit 4 according to FIG. 2 for example. Components and functions that correspond to those which have already been explained above with reference to FIGS. 1 to 21, and for example with reference to FIG. 2, bear the same reference signs and will not be discussed in detail again.

A mirror 53a of the mirror assembly 21 of the illumination optical unit 53, which can be used in place of the mirror 27, for example in the embodiment according to FIG. 2, has a mirror body 53b in the form of a pyramid with a pyramid tip 53c and a total of four lateral facets 53 d. The number of lateral facets may also be greater than 4 or else equal to 3.

Assuming an appropriate design of the mirror 53a, the mirror body 53b can also rotate when the second rotor portion 36, i.e. the rotor shaft of the mirror assembly 21 of the illumination optical unit 53, is rotated, with the result that the beam of the illumination light 16 is alternately reflected by different lateral facets 53d to the subsequent components of the illumination optical unit 53.

Assuming an appropriate synchronization of the rotational drive device 28 with the light source, the mirror 53a can be used to realize a pupil monopole in the pupil 39 of the illumination optical unit 53, in the case of which each light pulse from the light source 3 is transmitted to the same point in the pupil 39. Other illumination settings can also be realized, especially further forms of multipole illumination settings.

The illumination optical unit 53 has a further scanning mirror in the form of a polygon mirror 54 in the beam path downstream of the mirror assembly 21 and the deflection mirror 22.

In the case of the polygon mirror 54, polygon facets 55ᵢ (i=1 to 6), which in terms of their function fundamentally correspond to the polygon facets 40ᵢ of the embodiment of the polygon mirror 23 according to FIG. 17, are designed as NI mirrors for the illumination light 16, i.e. mirrors with an angle of incidence for the illumination light 16 which is regularly less than 60° and may also be less than 45°.

Scanning of an object field 5, rectangular in the case of the illumination optical unit 53, is once again illustrated in FIG. 22 by illumination light component beams 16₁ to 16₃ illustrating momentary scanning positions. Likewise for illustrative purposes, the object field 5, extending parallel to the xy-plane per se, is depicted in a plan view in FIG. 22.

The short rectangular extent also extends in the scanning direction y in the case of the rectangular object field 5.

In order to produce a microstructured or nanostructured component, the projection exposure apparatus 1 is used as follows. Initially, the reticle 7 and the wafer 13 are provided. Subsequently, a structure on the reticle 7 is projected onto a light-sensitive layer of the wafer 13 with the aid of the projection exposure apparatus 1. Then a microstructure or nanostructure on the wafer 13, and hence the microstructured component, is created by developing the light-sensitive layer. This component is a semiconductor component, for example a microchip, for example a memory chip.

What is claimed is:

1. A mirror assembly, comprising:
a mirror comprising a mirror body and a reflection surface; and
a rotational drive device for a reflection surface support portion of the mirror body,
wherein the rotational drive device comprises:
a first motor, comprising:
a stationary, first stator portion; and
a first rotor portion which is rotatable relative to the first stator portion about a first axis of rotation; and
a second motor, comprising:
a second stator portion which: is affixed to the first stator portion; coincides with the first rotor portion; or is affixed to the first rotor portion; and
a second rotor portion to which a rotor body portion of the mirror body affixed, the second rotor portion being rotatable relative to the second stator portion about a second axis of rotation,
wherein a normal to the reflection surface has an angle of greater than 0° with respect to the first axis of rotation and/or with respect to the second axis of rotation.

2. The mirror assembly of claim 1, wherein the two axes of rotation have an angle of greater than 0° with respect to one another.

3. The mirror assembly of claim 2, wherein the two axes of rotation intersect within the first stator portion.

4. The mirror assembly of claim 1, further comprising a motor controller configured to control at least one member selected from the group consisting of a rotational speed of the first motor, a rotational speed of the second motor, a phase of a position of the first rotor portion, and a phase of a position of the second rotor portion.

5. The mirror assembly of claim 1, wherein:
the mirror body has a two-piece design;
the mirror body comprises the reflection surface support portion and the rotor body portion; and
the reflection surface support portion is rotatably mounted on the rotor body portion.

6. The mirror assembly of claim 5, wherein the reflection surface support portion of the mirror body comprises a line portion of a fluid heat transfer medium line.

7. The mirror assembly of claim 1, wherein:
the two axes of rotation have an angle of greater than 0° with respect to one another; and
each of the first and second motors comprises a motor controller configured to control at least one member selected from the group consisting of a rotational speed of the first motor, a rotational speed of the second motor, a phase of a position of the first rotor portion, and a phase of a position of the second rotor portion.

8. The mirror assembly of claim 7, wherein:
the mirror body has a two-piece design;
the mirror body comprises the reflection surface support portion and the rotor body portion; and
the reflection surface support portion is rotatably mounted on the rotor body portion.

9. The mirror assembly of claim 1, wherein:
the two axes of rotation have an angle of greater than 0° with respect to one another; and
the mirror body has a two-piece design;
the mirror body comprises the reflection surface support portion and the rotor body portion; and
the reflection surface support portion is rotatably mounted on the rotor body portion.

10. An optical unit, comprising:
a mirror assembly comprising a first scanning mirror;
a second scanning mirror in a region of a pupil plane of the optical unit;
a motor controller configured to control a rotational speed and/or a rotational phase of the first and second scanning mirrors; and
a scan controller configured to scan an object field of the illumination optical unit,
wherein the scan controller is signal-connected to the motor controller, and the optical unit is an illumination optical unit.

11. The optical unit of claim 10, wherein the mirror assembly comprises:
a mirror comprising a mirror body and a reflection surface; and
a rotational drive device for a reflection surface support portion of the mirror body,
wherein the rotational drive device comprises:
a first motor, comprising:
a stationary, first stator portion; and
a first rotor portion which is rotatable relative to the first stator portion about a first axis of rotation; and
a second motor, comprising:
a second stator portion which: is affixed to the first stator portion; coincides with the first rotor portion; or is affixed to the first rotor portion; and
a second rotor portion to which a rotor body portion of the mirror body affixed, the second rotor portion being rotatable relative to the second stator portion about a second axis of rotation,
wherein a normal to the reflection surface has an angle of greater than 0° with respect to the first axis of rotation and/or with respect to the second axis of rotation, and the mirror of the mirror assembly is the first scanning mirror.

12. The optical unit of claim 11, wherein the second scanning mirror comprises a normal incidence mirror or a grazing incidence mirror.

13. A system, comprising:
an illumination optical unit according to claim 10; and
a light source,
wherein the system is an illumination system.

14. The system of claim 13, wherein the light source is a free electron laser.

15. They system of claim 13, wherein the light source is a pulsed light source.

16. The system of claim 13, wherein the mirror assembly comprises:
a mirror comprising a mirror body and a reflection surface; and
a rotational drive device for a reflection surface support portion of the mirror body,
wherein the rotational drive device comprises:
a first motor, comprising:
a stationary, first stator portion; and
a first rotor portion which is rotatable relative to the first stator portion about a first axis of rotation; and
a second motor, comprising:
a second stator portion which: is affixed to the first stator portion; coincides with the first rotor portion; or is affixed to the first rotor portion; and
a second rotor portion to which a rotor body portion of the mirror body affixed, the second rotor portion being rotatable relative to the second stator portion about a second axis of rotation,
wherein a normal to the reflection surface has an angle of greater than 0° with respect to the first axis of rotation and/or with respect to the second axis of rotation, and the mirror of the mirror assembly is the first scanning mirror.

17. An apparatus, comprising:
an illumination system comprising a light source and an illumination optical unit according to claim 10; and
a projection optical unit configured to image an object field into an image field,
wherein the apparatus is a lithography projection exposure apparatus.

18. The apparatus of claim 17, wherein the mirror assembly comprises:
a mirror comprising a mirror body and a reflection surface; and
a rotational drive device for a reflection surface support portion of the mirror body,
wherein the rotational drive device comprises:
a first motor, comprising:
a stationary, first stator portion; and
a first rotor portion which is rotatable relative to the first stator portion about a first axis of rotation; and
a second motor, comprising:
a second stator portion which: is affixed to the first stator portion; coincides with the first rotor portion; or is affixed to the first rotor portion; and
a second rotor portion to which a rotor body portion of the mirror body affixed, the second rotor portion being rotatable relative to the second stator portion about a second axis of rotation,
wherein a normal to the reflection surface has an angle of greater than 0° with respect to the first axis of rotation and/or with respect to the second axis of rotation, and the mirror of the mirror assembly is the first scanning mirror.

19. A method of using a lithography projection exposure apparatus comprising an illumination system and a projection optical unit, the method comprising:
using the illumination system to illuminate an object in an object field of the projection optical unit; and
using the projection optical unit to image the illuminated object into an image field of the projection optical unit,
wherein the illumination system comprises an illumination optical unit according to claim 10.

20. The method of claim 19, wherein the mirror assembly comprises:
a mirror comprising a mirror body and a reflection surface; and
a rotational drive device for a reflection surface support portion of the mirror body,
wherein the rotational drive device comprises:
a first motor, comprising:
a stationary, first stator portion; and
a first rotor portion which is rotatable relative to the first stator portion about a first axis of rotation; and
a second motor, comprising:
a second stator portion which: is affixed to the first stator portion; coincides with the first rotor portion; or is affixed to the first rotor portion; and
a second rotor portion to which a rotor body portion of the mirror body affixed, the second rotor portion being rotatable relative to the second stator portion about a second axis of rotation,
wherein a normal to the reflection surface has an angle of greater than 0° with respect to the first axis of rotation and/or with respect to the second axis of rotation, and the mirror of the mirror assembly is the first scanning mirror.
